(19) United States
(12) Patent Application Publication
(10) Pub. No.: US 2021/0267070 A1
(43) Pub. Date: Aug. 26, 2021

(54) ELECTRICAL CONNECTION BOX

(71) Applicants: Sumitomo Wiring Systems, Ltd., Yokkaichi-shi, Mie (JP); Toyota Jidosha Kabushiki Kaisha, Toyota-shi, Aichi (JP)

(72) Inventors: Masakazu Okumura, Yokkaichi-shi, Mie (JP); Akihiro Oda, Yokkaichi-shi, Mie (JP); Tatsuya Daidoji, Yokkaichi-shi, Mie (JP); Ryoma Hamada, Yokkaichi-shi, Mie (JP); Yoshiharu Sato, Yokkaichi-shi, Mie (JP); Shinji Oshita, Toyota-shi, Aichi (JP); Nobutoshi Hagiwara, Toyota-shi, Aichi (JP); Takumi Matsumoto, Toyota-shi, Aichi (JP)

(21) Appl. No.: 17/251,643

(22) PCT Filed: Jun. 5, 2019
(86) PCT No.: PCT/JP2019/022261

§ 371 Date: Dec. 11, 2020

(30) Foreign Application Priority Data
Jun. 15, 2018 (JP) 2018-114773

(51) Int. Cl. H05K 5/00; B60R 16/023

(52) U.S. Cl. CPC H05K 5/0056; H05K 5/0069; B60R 16/0239

(57) ABSTRACT

An electrical connection box includes a box body for accommodating an electrical part, and one or a plurality of connection terminals provided on at least one surface of the box body, in which the box body has a lid body provided on one surface different from the one surface on which the connection terminal is provided, the lid body has a shape of a polygonal plate, and a flow path for a liquid is provided along at least one side of the lid body on the inner surface side of the lid body. The flow path may be defined by a first wall erected on the inner surface side of the lid body along an edge of the one side of the lid body, and a second wall separated from the first wall and erected on the inner surface side of the lid body along the first wall.

### CROSS-REFERENCE TO RELATED APPLICATIONS

This application is the U.S. national stage of PCT/JP2019/022261 filed on Jun. 5, 2019, which claims priority of Japanese Patent Application No. JP 2018-114773 filed on Jun. 15, 2018, the contents of which are incorporated herein.

### TECHNICAL FIELD

The present disclosure relates to an electrical connection box that accommodates an electrical part such as a relay or a fuse and includes a connection terminal to which a power line, a signal line, etc. is connected.

### BACKGROUND

Conventionally, a plurality of electrical components has been mounted on a vehicle. An electrical component is connected to a power source such as a battery through a power line that supplies power, and is connected to a control device through a signal line that transmits a control signal. In many cases, an electrical part such as a relay or a fuse interposes in the power line that connects the electrical component and the power source. The power line is appropriately arranged in the vehicle and is connected to the electrical component, the power source, etc. In recent years, the number of electrical components mounted on the vehicle has been increasing due to diversification of functions of the vehicle. As the number of electrical components increases, the number of power lines arranged in the vehicle increases, and the number of electrical parts interposed in the power line tends to increase.

A plurality of electrical parts such as the relay or the fuse is provided in the vehicle to protect a circuit. The plurality of electrical parts is collectively accommodated in an electrical connection box (so-called junction box or relay box). The electrical connection box is fixed at a proper position of the vehicle, and the power line from the power source and the power line to the electrical component are connected to the electrical connection box. Further, the electrical connection box may have a built-in control device for controlling the accommodated electrical parts, or may have a control device provided in a separate housing attached thereto. Japanese Patent Laid-Open Publication No. 2013-150504 and Japanese Patent Laid-Open Publication No. 2016-047662 describe configurations of such an electrical connection box.

The electrical connection box accommodates a plurality of electrical parts therein, and, for example, it is necessary to protect the electrical parts from infiltration of a liquid existing in the vehicle, such as drinking water of a passenger or condensed water of window glass.

The present disclosure has been made in view of such circumstances, and an object thereof is to provide an electrical connection box that can be expected to protect accommodated electrical parts from a liquid infiltrating from the outside.

### SUMMARY

An electrical connection box according to this aspect includes a box body, a connection terminal, and a lid body, in which the box body has a polyhedron type for accommodating an electrical part, the connection terminal is provided on at least one surface of the box body, the lid body has a shape of a polygonal plate provided on one surface different from the one surface of the box body on which the connection terminal is provided, and a flow path for a liquid is provided on an inner surface side of the lid body along at least one side of the lid body.

According to the above description, it can be expected to protect electrical parts accommodated in an electrical connection box from a liquid infiltrating from the outside.

### BRIEF DESCRIPTION OF THE DRAWINGS

FIG. 1 is a perspective view illustrating a configuration of an electrical connection box according to the present embodiment.

FIG. 2 is a perspective view illustrating a configuration of the electrical connection box according to the present embodiment.

FIG. 3 is a perspective view illustrating a configuration of the electrical connection box according to the present embodiment.

FIG. 4 is an exploded perspective view illustrating a configuration of the electrical connection box according to the present embodiment.

FIG. 5 is a perspective view illustrating a configuration of a lid body of the electrical connection box.

FIG. 6 is a perspective view illustrating a configuration of the lid body of the electrical connection box.

FIG. 7 is a plan view illustrating a configuration of the lid body of the electrical connection box.

FIG. 8 is a side view illustrating a configuration of the lid body of the electrical connection box.

FIG. 9 is a bottom view illustrating a configuration of the lid body of the electrical connection box.

FIG. 10 is a cross-sectional view illustrating a configuration of the electrical connection box.

FIG. 11 is a schematic diagram for description of a flow path of the electrical connection box.

FIG. 12 is a plan view illustrating a configuration of a lid body of an electrical connection box according to a modification.

### DETAILED DESCRIPTION OF PREFERRED EMBODIMENTS

First, embodiments of the present disclosure will be listed and described. Further, at least a part of the embodiments described below may be arbitrarily combined.

An electrical connection box according to this aspect includes a box body, a connection terminal, and a lid body, in which the box body has a polyhedron type for accommodating an electrical part, the connection terminal is provided on at least one surface of the box body, the lid body has a shape of a polygonal plate provided on one surface different from the one surface of the box body on which the connection terminal is provided, and a flow path for a liquid is provided on an inner surface side of the lid body along at least one side of the lid body.

In this aspect, the electrical connection box includes the box body having the polyhedron type for accommodating the electrical part, and the connection terminal for connecting a power line, a communication line, etc. is provided on at least one surface of the box body. The box body of the electrical connection box has the lid body, and by mounting the lid body after housing the electrical part, the box body is closed, and the electrical part on the inside is protected. The lid body has the shape of the polygonal plate, and the flow path for the liquid is provided on the inner surface side along at least one side. In this way, even when the liquid infiltrates into the box body from the edge portion, etc. of the lid body attached to the box body, the infiltrated liquid can flow along the flow path, and it is possible to hinder the liquid from reaching the electrical parts in the box body.

It is preferable that the flow path is defined by a first wall erected on the inner surface side of the lid body along an edge of the one side of the lid body, and a second wall separated from the first wall and erected on the inner surface side of the lid body along the first wall.

In this aspect, the first wall is erected on the inner surface side of the lid body along an edge of the one side of the lid body. In addition, the second wall is separated from the first wall and erected on the inner surface side of the lid body along the first wall. A flow path can be formed between the first wall and the second wall provided along the edge of the one side of the lid body. In this way, the flow path can be easily provided without impairing the strength, etc. of the lid body.

It is preferable that a through-hole for discharging a liquid flowing through the flow path to an outside of the box body is formed in the box body.

In this aspect, the through-hole for discharging a liquid flowing through the flow path to an outside of the box body is formed in the box body. In this way, it is possible to efficiently discharge the liquid flowing through the flow path to the outside of the box body from the through-hole.

It is preferable that the flow path is provided on one side adjacent to one surface of the box body provide with the connection terminal in the lid body in a mounted state.

In this aspect, the connection terminal is provided on at least one surface of the box body. The lid body is provided with the flow path along one side adjacent to one surface on which the connection terminal is provided in a state of being mounted on the box body. The surface on which the connection terminal is provided may be inferior in airtightness to other surfaces. By providing the flow path in a position adjacent to the surface on which the connection terminal is provided, it is possible to protect the electrical part on the inside from the liquid infiltrating into the box body from the side of the surface on which the connection terminal is provided.

It is preferable that the electrical connection box is mounted on a vehicle, and the flow path is provided along a vertical direction in a state in which the electrical connection box is mounted on the vehicle.

In this aspect, for example, the electrical connection box is mounted on the vehicle by being fixed to the vehicle body of the vehicle. The flow path of the lid body of the electrical connection box is provided in the vertical direction in a state where the electrical connection box is mounted on the vehicle. In this way, it is possible to allow the liquid infiltrating into the box body and reaching the flow path to flow from an upper part to a lower part of the flow path.

An electrical connection box according to this aspect includes a box body, a connection terminal, and a wall, in which the box body has a polyhedron type for accommodating an electrical part, the connection terminal is provided to protrude from an opening formed in at least one surface of the box body, and the wall is erected along an edge portion of the opening at a predetermined interval from the edge portion in the box body.

In this aspect, the electrical connection box includes the box body having polyhedron type for accommodating an electrical part, and the connection terminal for connecting a power line, a communication line, etc. is provided to protrude from an opening formed in at least one surface of the box body. The wall is erected along an edge portion of the opening at a predetermined interval from the edge portion in the box body. In this way, even when the liquid infiltrates the inside from the opening of the box body, it is possible to hinder the liquid from reaching the electrical part in the box body by the wall in the box body.

Specific examples of an electrical connection box according to an embodiment of the present disclosure will be described below with reference to the drawings. Note that the present disclosure is not limited to these exemplifications, and is shown by the claims, and is intended to include meanings equivalent to the claims and all modifications within the scope.

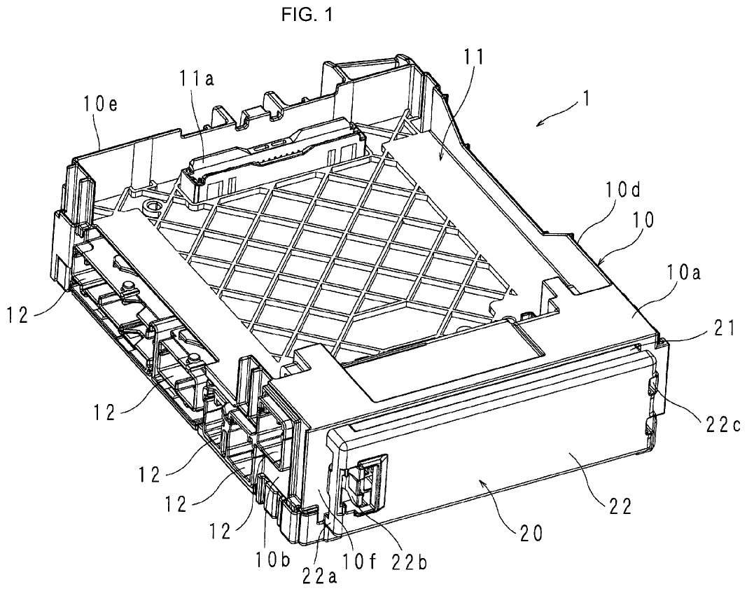

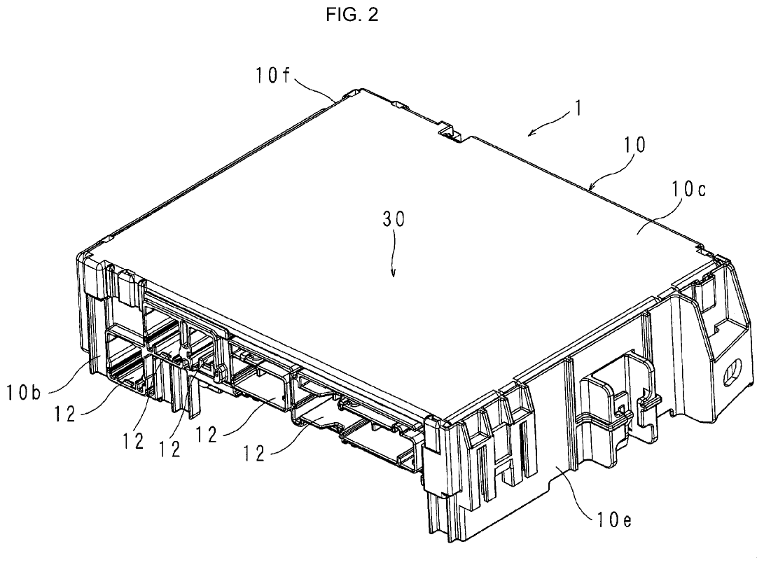

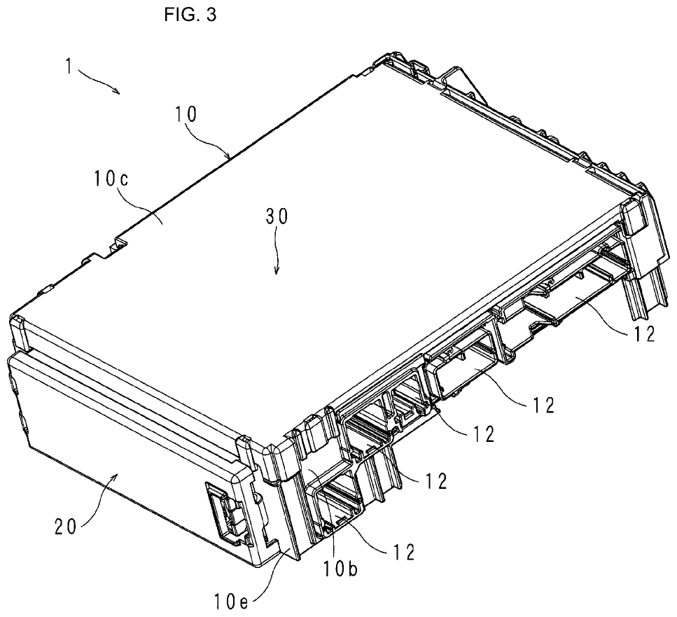

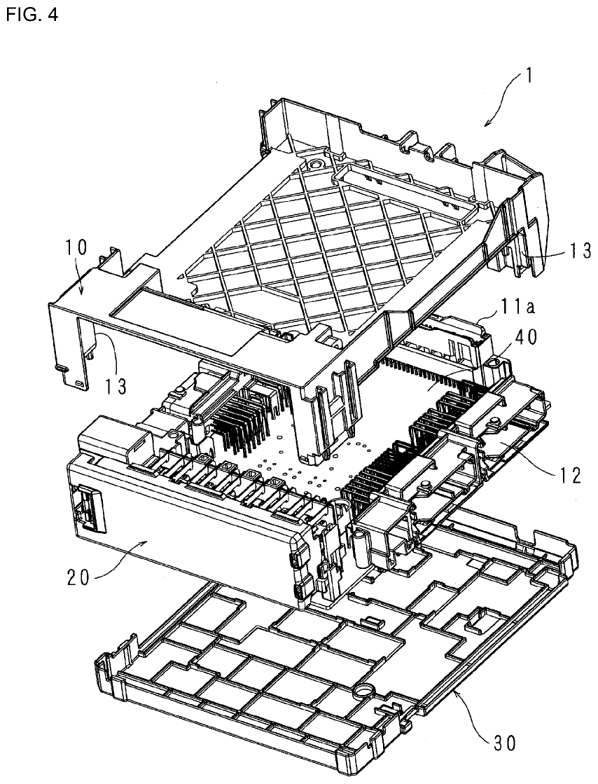

FIGS. 1 to 3 are perspective views illustrating configurations of an electrical connection box according to the present embodiment. In the present embodiment, description will be made on the assumption that FIG. 1 corresponds to a front surface side of the electrical connection box and FIGS. 2 and 3 correspond to a back surface side of the electrical connection box. FIG. 4 is an exploded perspective view illustrating a configuration of the electrical connection box according to the present embodiment. The electrical connection box 1 according to the present embodiment is a device which is fixed to, for example, a vehicle body of a vehicle (not illustrated), to which a plurality of cables such as power lines or communication lines arranged inside the vehicle is connected, and which electrically connects the plurality of cables to each other. The electrical connection box 1 is a device that can be referred to as a name such as a junction box, a relay box, or a repeater. Electrical parts such as a relay and a fuse are accommodated in the electrical connection box 1, and the plurality of cables is electrically connected via these electrical parts. Note that even though a circuit board 40 on which the electrical parts accommodated in the electrical connection box 1 is illustrated in the exploded perspective view illustrated in FIG. 4, the electrical parts are not illustrated.

The electrical connection box 1 is a flat rectangular parallelepiped box body including a main body 10 that accommodates the circuit board 40, and a lid body 30 that closes an open portion of the main body 10. The electrical connection box 1 is configured such that the circuit board 40 is housed inside from the open portion on the back surface side of the main body 10 and the lid body 30 is fixed to the main body 10 so as to close the open portion. In the present embodiment, six surfaces l0a to 10f of the electrical connection box 1 are distinguished by a front surface 10a, a left side surface 10b, a back surface 10c, a right side surface 10d, an upper surface 10e, and a lower surface 10f for convenience. The electrical connection box 1 is fixed to the vehicle body in the vehicle with the upper surface l0e facing upward and the lower surface 10f facing downward. The front surface l0a and the back surface 10c of the electrical connection box 1 are wide surfaces located on the front and back sides. The left side surface 10b, the right side surface 10d, the upper surface l0e and the lower surface 10f are elongated surfaces adjacent to the front surface 10a and the back surface 10c.

The circuit board 40 is in a shape of a rectangular plate, on which electrical parts are mounted and a wiring pattern included in an electric circuit using the electrical parts is formed. A connection portion 11a, to which a control unit (not illustrated) provided as a separate housing is electrically connected, is connected and fixed to an edge portion of an upper side of the circuit board 40. The connection portion 11a has a configuration in which a metal terminal for performing electrical connection is provided in a square tubular case provided with an elongated rectangular opening, and the square tubular case is provided to project substantially perpendicularly to a plate surface of the circuit board 40.

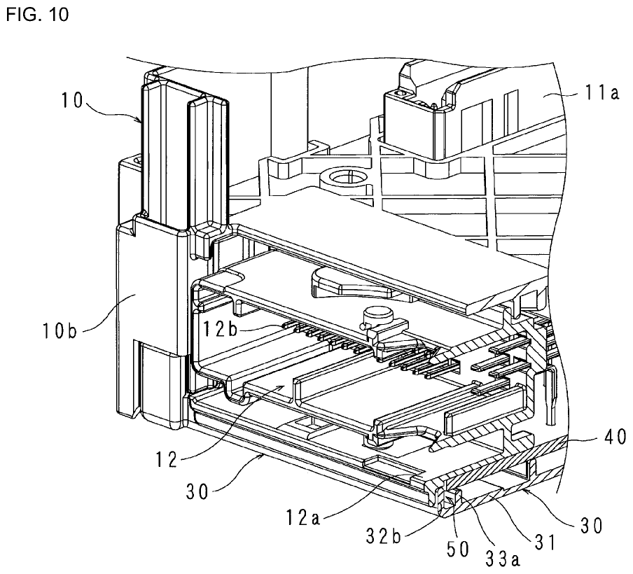

A plurality of connection portions 12 is connected and fixed to each of edge portions on the left and right sides of the circuit board 40. The connection portions 12 are used to connect the cables, and have sizes, shapes, etc. suitable for types and standards of the cables to be connected. The plurality of connection portions 12 provided in the electrical connection box 1 according to the present embodiment is different in size, shape, etc., and a metal terminal 12b (see FIG. 10) for performing electrical connection is provided in a square tubular case 12a provided with a square or rectangular opening. A rectangular columnar or rectangular tubular connection portion provided at a tip of a cable is inserted and fit into the case 12a of the connection portions 12 of the electrical connection box 1, thereby electrically connecting an electric wire in the cable and the metal terminal 12b of the connection portions 12 to each other.

In addition, a fuse accommodating portion 20 that accommodates a fuse is provided at an edge portion of a lower side of the circuit board 40. The fuse accommodating portion 20 includes a rectangular parallelepiped box body 21 for accommodating the fuse, and a lid body 22 for covering an opening of the box body 21 for inserting and removing the fuse. Although not illustrated, the box body 21 is divided into a plurality of small rooms, and a fuse is housed in each small room. The lid body 22 that covers a protruding end surface of the box body 21 is a rectangular plate that is slightly larger than the protruding end surface, and is provided with a peripheral wall 22a surrounding a peripheral edge portion. The lid body 22 is detachably attached to the box body 21 by engaging engagement portions 22b and 22c provided on both sides in a longitudinal direction with engagement portions provided on the box body 21.

A recess 11 having a substantially square shape when viewed from the front, which occupies an area of half or more of the front surface 10a, is formed on the front surface 10a of the electrical connection box 1. A control unit, which is provided as a separate housing, is assembled in the recess 11 of the electrical connection box 1. A rectangular opening, which is long along an upper side of the front surface 10a, is formed at a position near the upper side on a bottom surface of the recess 11, and the connection portion 11a provided on the circuit board 40 accommodated inside the electrical connection box 1 projects to the outside through this opening. The housing of the control unit is fit into the recess 11 of the electrical connection box 1, and the connection portion of the control unit and the connection portion Ila of the electrical connection box 1 are connected, so that the control unit is assembled into the electrical connection box 1.

On each of the left side surface 10b and the right side surface 10d of the electrical connection box 1, an opening 13 which is long in a longitudinal direction of the surface (vertical direction of the electrical connection box 1) is formed. The connection portions 12 provided on the left and right sides of the circuit board 40 accommodated inside the electrical connection box 1 project to the outside through the openings 13 of the electrical connection box 1. In addition, on the lower surface 10f of the electrical connection box 1, an opening which is long in a longitudinal direction of the lower surface 10f (left-right direction of the electrical connection box 1) is formed. The fuse accommodating portion 20 provided on the lower side of the circuit board 40 accommodated in the electrical connection box 1 projects to the outside through the opening in the lower surface 10f of the electrical connection box 1.

As described above, the electrical connection box 1 is configured by combining the main body 10 and the lid body 30 that can be removed from the main body 10. The main body 10 is included in the front surface 10a of the electrical connection box 1 and a part of the left side surface 10b, the right side surface 10d, the upper surface 10e and the lower surface 10f of the electrical connection box 1. The lid body 30 is included in the back surface 10c of the electrical connection box 1 and a part of the left side surface 10b, the right side surface 10d, the upper surface 10e and the lower surface 10f of the electrical connection box 1. The electrical connection box 1 is assembled by accommodating the circuit board 40, to which the relay, the connection portion 11a, the connection portions 12, the fuse accommodating portion 20, etc. are fixed, in the main body 10 from an opening part of the back surface and attaching the lid body 30 on the back surface side of the main body 10 to cover the opening. For example, the lid body 30 can be attached to the main body 10 of the electrical connection box 1 by various methods such as engagement using a claw-shaped portion or screwing.

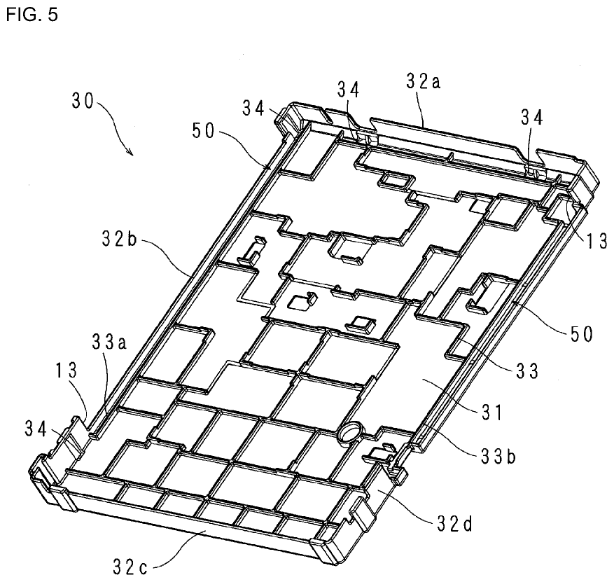

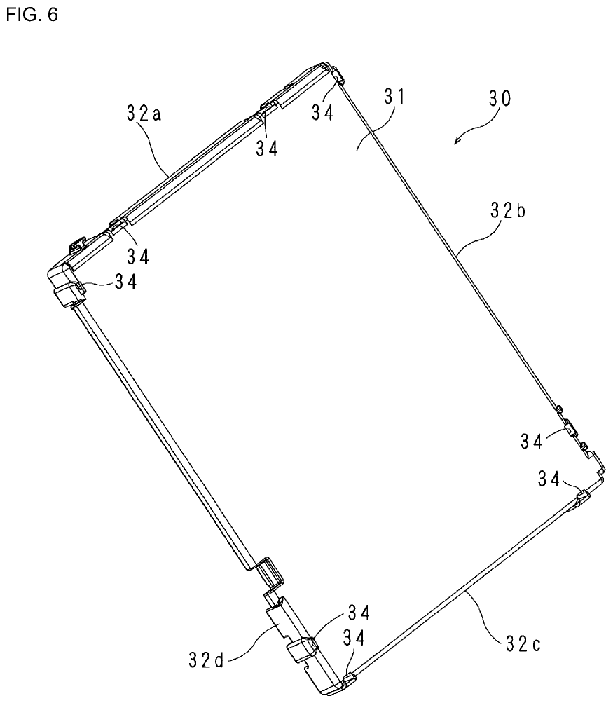

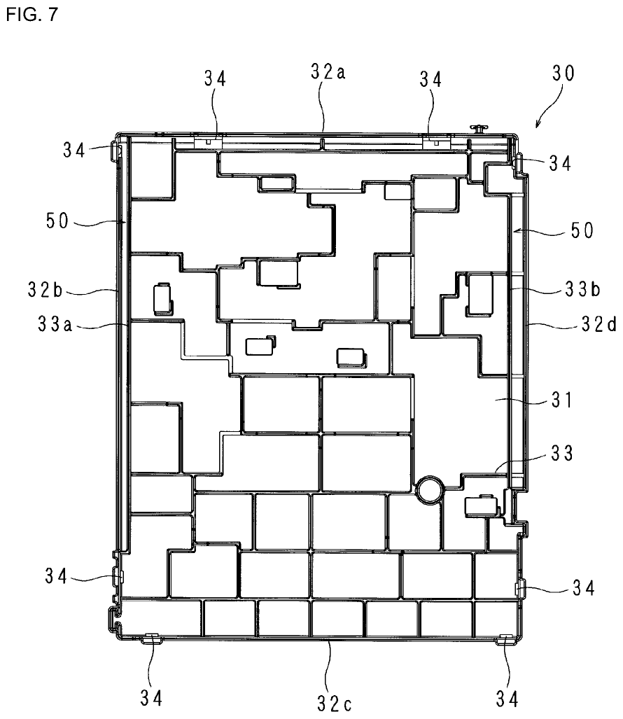

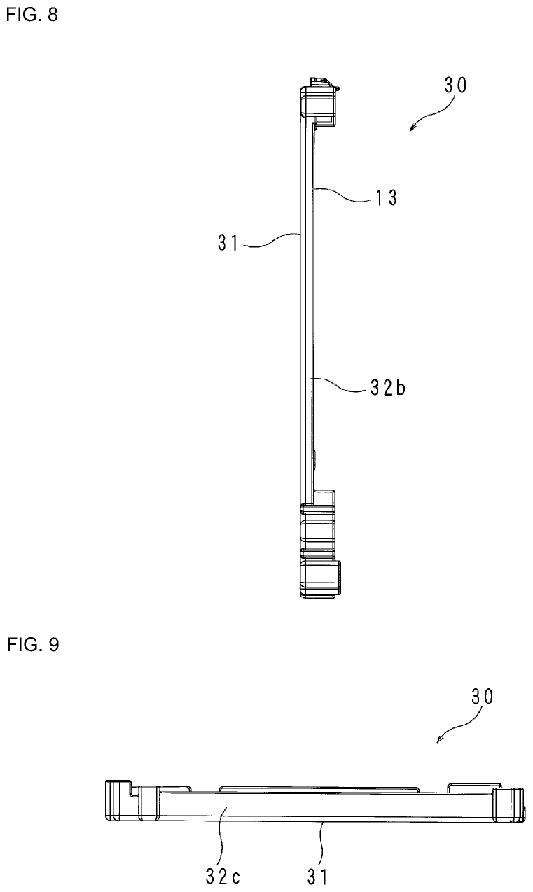

FIGS. 5 and 6 are perspective views illustrating configurations of the lid body 30 of the electrical connection box 1, FIG. 5 illustrates a configuration of an inner side the lid body 30, and FIG. 6 illustrates a configuration of an outer side of the lid body 30. Note that the inner side of the lid body 30 refers to a side located on the inside of the electrical connection box 1 when the lid body 30 is attached to the main body 10. In addition, FIG. 7 is a plan view illustrating a configuration of the lid body 30 of the electrical connection box 1, FIG. 8 is a side view illustrating a configuration of the lid body 30 of the electrical connection box 1, and FIG. 9 is a bottom view illustrating a configuration of the lid body 30 of the electrical connection box 1.

The lid body 30 of the electrical connection box 1 has a bottom plate 31 having a shape of a rectangular plate, and a first wall 32a to a fourth wall 32d erected on four sides of the bottom plate 31. The bottom plate 31 is included in the back surface 10c of the electrical connection box 1 when the lid body 30 is attached to the main body 10 of the electrical connection box 1. The first wall 32a to the fourth wall 32d are erected substantially vertically from the four sides of the bottom plate 31 so as to surround an inner surface of the bottom plate 31. When the lid body 30 is attached to the main body 10 of the electrical connection box 1, the first wall 32a of the lid body 30 is included in a part of the upper surface 10e of the electrical connection box 1, the second wall 32b is included in a part of the left side surface 10b of the electrical connection box 1, the third wall 32c is included in a part of the lower surface 10f of the electrical connection box 1, and the fourth wall 32d is included in a part of the right side surface 10d of the electrical connection box 1.

Further, in each of the first wall 32a to the fourth wall 32d, through-holes 34 are formed near both ends in the longitudinal direction thereof. The plurality of through-holes 34 is formed near boundaries between the bottom plate 31 and the first wall 32a to the fourth wall 32d so as to penetrate the front and back surfaces of the lid body 30, respectively. Claw-shaped projections provided on the main body 10 of the electrical connection box 1 are inserted into the plurality of through-holes 34, and the lid body 30 is attached to the main body 10 by engaging claw portions of the projections with edge portions of the through-holes 34.

In addition, on the inner surface of the bottom plate 31, a plurality of ribs 33 is erected vertically and horizontally. The ribs 33 support the circuit board 40 inside the electrical connection box 1 by abutting on the back surface of the circuit board 40 accommodated inside the electrical connection box 1. Shapes and the number of ribs 33 provided on the bottom plate 31 are appropriately determined according to the shape of the circuit board 40, the shapes of the electrical parts mounted on the circuit board 40, etc.

In addition, on the bottom plate 31 of the lid body 30, a rib 33a is provided along the second wall 32b of the lid body 30 included in a part of the left side surface 10b of the electrical connection box 1 and substantially in parallel with the second wall 32b at a predetermined distance. Similarly, on the bottom plate 31 of the lid body 30, a rib 33b is provided along the fourth wall 32d of the lid body 30 included in a part of the right side surface 10d of the electrical connection box 1 and substantially in parallel with the fourth wall 32d at a predetermined distance. In this way, on the lid body 30, groove-shaped spaces are provided between the second wall 32b and the rib 33a and between the fourth wall 32d and the rib 33b.

FIG. 10 is a cross-sectional view illustrating a configuration of the electrical connection box 1, and is an enlarged view of a periphery of the left side surface 10b of the electrical connection box 1 in a cross section when the electrical connection box 1 is cut along a plane substantially parallel to the upper surface 10e. The circuit board 40 to which the relay, the connection portions 12, etc. are connected and fixed is accommodated in the main body 10 of the electrical connection box 1, and the plurality of connection portions 12 projects from the left side surface 10b of the electrical connection box 1 in a state where the lid body 30 is attached to the back surface of the main body 10. The connection portions 12 have the square tubular case 12a and a plurality of metal terminals 12b held in the back of the case 12a. The connection portions 12 are fixed to the circuit board 40 in a state where a part of the back surface of the case 12a is in contact with an edge portion of a front surface of the circuit board 40. In the connection portions 12 fixed to the circuit board 40, the case 12a protrudes from the inside of the electrical connection box 1 to the outside through the opening 13 formed in the left side surface 10b of the electrical connection box 1.

The opening 13 of the electrical connection box 1 from which the connection portions 12 project is rectangular, edge portions of a rectangular cutout formed in the main body 10 correspond to sides on an upper side, a front surface side, and a lower side of the opening 13, and an edge portion of the second wall 32b of the lid body 30 fixed to the main body 10 corresponds to a side on a back surface side of the opening 13. The back surface of the case 12a of the connection portions 12 protruding from the opening 13 of the electrical connection box 1 comes into contact with the second wall 32b of the lid body 30 fixed to the main body 10. In addition, the circuit board 40 accommodated in the electrical connection box 1 is a rectangular plate, and a left end portion thereof reaches the vicinity of the inner surface of the second wall 32b of the lid body 30 included in a part of the left side surface 10b of the electrical connection box 1. The rib 33a provided substantially parallel to the second wall 32b of the lid body 30 comes into contact with the back surface of the circuit board 40 accommodated in the electrical connection box 1. In this way, a flow path 50 that allows a liquid to flow along a vertical direction is formed at a left end of the back surface in the electrical connection box 1. The flow path 50 is a space defined and surrounded by the bottom plate 31 of the lid body 30, the second wall 32b of the lid body 30, the rib 33a of the lid body 30, and the circuit board 40 accommodated in the electrical connection box 1. Note that a sectional configuration of the right side surface 10d of the electrical connection box 1 is a similar configuration, and thus illustration and description thereof will be omitted.

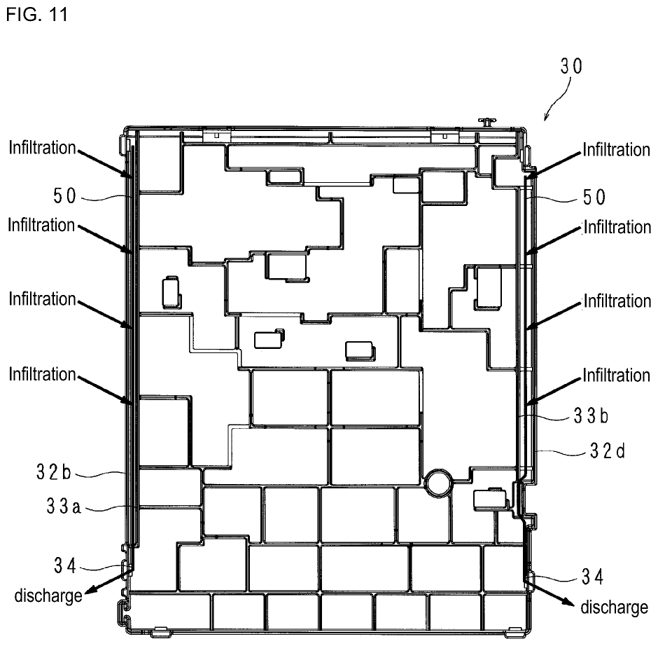

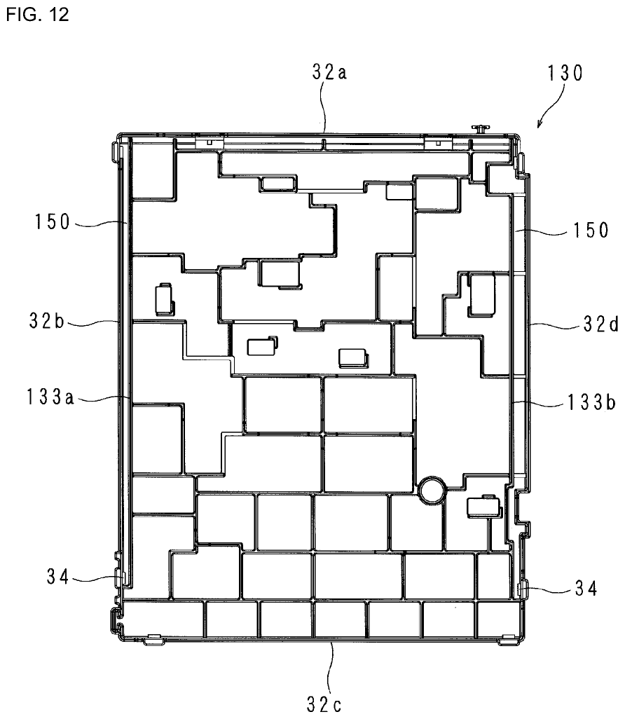

FIG. 11 is a schematic diagram for description of the flow path 50 of the electrical connection box 1, and illustrates a flow of a liquid from infiltration to discharge by arrows in the plan view of the lid body 30 illustrated in FIG. 7. For example, there is concern that the liquid may infiltrate into the electrical connection box 1 from a gap between the electrical connection box 1 and the connection portions 12 protruding from the left side surface 10b of the electrical connection box 1, particularly a gap between the back surface of the case 12a of the connection portions 12 and the second wall 32b of the lid body 30. The infiltrated liquid reaches the space between the second wall 32b of the lid body 30 and the rib 33a, that is, the flow path 50. The flow path 50 is provided so as to extend in the vertical direction in a state where the electrical connection box 1 is mounted on the vehicle. Therefore, the liquid reaching the flow path 50 flows inside the electrical connection box 1 along the flow path 50 from top to bottom.

As described above, the through-hole 34 for mounting the lid body 30 on the main body 10 is formed in the second wall 32b of the lid body 30. The liquid infiltrating into the electrical connection box 1 and flowing from the top to the bottom in the flow path 50 reaches the through-hole 34 along the inner surface of the electrical connection box 1 and is discharged to the outside of the electrical connection box 1 from the through-hole 34. That is, the through-hole 34 provided in a lower part of the electrical connection box 1 is a hole for mounting the lid body 30 and a drain hole used to discharge the liquid in the electrical connection box 1 to the outside. However, in the electrical connection box 1, a through-hole for discharge may be formed separately from a hole for mounting the lid body 30.

The electrical connection box 1 according to the present embodiment having the above configuration is a rectangular parallelepiped box body that accommodates the circuit board 40 on which electrical parts such as a relay are mounted. One or a plurality of connection portions 12 for connecting cables is provided on the left side surface 10b and the right side surface 10d of the electrical connection box 1. The electrical connection box 1 has the lid body 30 attached to the main body 10. The main body 10 is closed by mounting the lid body 30 on the main body 10 accommodating the electrical parts, and the electrical parts on the inside are protected. The lid body 30 has a shape of a rectangular plate, and the flow path 50 of the liquid is provided along each of both left and right sides on a surface corresponding to the inside of the electrical connection box 1. In this way, even when the liquid infiltrates into the electrical connection box 1 from the edge portion of the lid body 30 attached to the main body 10, etc., the infiltrated liquid can flow along the flow path 50, and it is possible to hinder the liquid from reaching the electrical parts in the electrical connection box 1.

On the bottom plate 31 of the lid body 30, the second wall 32b (first wall) is erected along an edge portion of a left side, and the fourth wall 32d (first wall) is erected along an edge portion of a right side. Further, on the bottom plate 31, the rib 33a (second wall) is erected apart from the second wall 32b and along the second wall 32b, and the rib 33b (second wall) is erected apart from the fourth wall 32d and along the fourth wall 32d. In this way, the flow path 50 can be formed between the second wall 32b and the rib 33a of the lid body 30, and the flow path 50 can be formed between the fourth wall 32d and the rib 33b. The flow path 50 can be easily provided on the lid body 30 without impairing the strength, etc. of the lid body 30.

In addition, in the electrical connection box 1, the through-hole 34 for discharging the liquid flowing through the flow path 50 to the outside is formed. In this way, it is possible to efficiently discharge the liquid flowing through the flow path 50 to the outside of the electrical connection box 1 from the through-hole 34.

The plurality of connection portions 12 is provided on each of the left side surface 10b and the right side surface 10d of the electrical connection box 1. On the lid body 30, the flow path 50 is provided along each of the left side and the right side of the bottom plate 31 adjacent to the left side surface 10b and the right side surface 10d on which the connection portions 12 are provided in a state of being mounted on the main body 10. The surface on which the connection portions 12 are provided may be inferior in liquid tightness when compared to the other surfaces. By providing the flow path 50 at a location adjacent to the surface on which the connection portions 12 are provided, it is possible to protect the electrical parts on the inside from the liquid infiltrating into the electrical connection box 1 from the side of the surface on which the connection portions 12 are provided.

In addition, the electrical connection box 1 is fixed to the vehicle body of the vehicle and mounted on the vehicle. The flow path 50 of the lid body of the electrical connection box 1 is provided along a vertical direction in a state where the electrical connection box 1 is mounted on the vehicle. As a result, it is possible to allow the liquid infiltrating into the electrical connection box 1 and reaching the flow path 50 to flow from an upper part to a lower part of the flow path 50.

In the present embodiment, the connection portions 12 are provided to protrude from the opening 13 formed on each of the left side surface 10b and the right side surface 10d in the rectangular parallelepiped electrical connection box 1 that accommodates the electrical parts. In the electrical connection box 1, the ribs 33a and 33b (walls) are erected along the edge portion of the opening 13 at a predetermined interval from the edge portion. In this way, even when the liquid infiltrates the inside from the opening 13 of the electrical connection box 1, it is possible to hinder the liquid from reaching the electrical parts in the electrical connection box 1 by the ribs 33a and 33b of the electrical connection box 1.

Note that even though the electrical connection box 1 has the rectangular parallelepiped shape in the present embodiment, the shape is not limited thereto. For example, it is possible to adopt various shapes such as a cylindrical shape and a prismatic shape. Similarly, the shape of the lid body 30 may be various shapes other than the rectangular plate shape. Further, even though the connection portions 12 are provided on each of the two surfaces of the left side surface 10b and the right side surface 10d of the electrical connection box 1, the configuration is not limited thereto, and the connection portions 12 may be provided on one surface or three or more surfaces of the electrical connection box 1. In addition, the electrical connection box 1 may not have the recess 11 for assembling the control unit or the fuse accommodating portion 20 for accommodating the fuse. In addition, even though the electrical connection box 1 is mounted on the vehicle, the configuration is not limited thereto, and the electrical connection box 1 can be used in various places other than the vehicle. The electrical parts accommodated in the electrical connection box 1 are not limited to the relay, the fuse, etc., and various other types of electrical parts may be accommodated.

In addition, the shape, etc. of the electrical connection box 1 illustrated in the figures are examples, and the shapes, etc. are not limited thereto. In addition, the shapes, arrangement, etc. of the plurality of ribs 33 formed on the bottom plate 31 of the lid body 30 are not limited to those illustrated in the figures. However, the ribs 33a and 33b included in the flow path 50 are provided on the lid body 30. In addition, the ribs 33a and 33b included in the flow path 50 come into contact with the back surface of the circuit board 40 accommodated in the electrical connection box 1. However, the configuration is not limited thereto. For example, the ribs 33a and 33b may come into contact with the case 12a of the connection portions 12.

### Modification

An electrical connection box 1 according to a modification has a configuration in which the shapes of the ribs 33a and 33b included in the flow path 50 are changed with respect to the lid body 30 of the electrical connection box 1 according to the embodiment described above. For example, as illustrated in FIG. 7, the ribs 33a and 33b of the lid body 30 described above are provided along the opening 13 of the electrical connection box 1 from which the connection portions 12 project to a position of a lower end of the opening 13.

FIG. 12 is a plan view illustrating a configuration of a lid body 130 of the electrical connection box 1 according to the modification. In the lid body 130 of the electrical connection box 1 according to the modification, a rib 133a is provided along a second wall 32b, and a rib 133b is provided along a fourth wall 32d, thereby forming flow paths 150 through which a liquid flows. The ribs 133a and 133b of the lid body 130 according to the modification have lower portions extending to positions where the through-holes 34 are formed. In this way, in the electrical connection box 1 according to the modification, the flow paths 150 directly communicate with the through-holes 34, and drainage from the through-holes 34 can be performed more efficiently.

1. An electrical connection box, comprising:
a box body;
a connection terminal; and
a lid body,
wherein the box body has a polyhedron type for accommodating an electrical part,
the connection terminal is provided on at least one surface of the box body,
the lid body has a shape of a polygonal plate provided on one surface different from the one surface of the box body on which the connection terminal is provided, and
a flow path for a liquid is provided on an inner surface side of the lid body along at least one side of the lid body.

2. The electrical connection box according to claim 1, wherein the flow path is defined by:
a first wall erected on the inner surface side of the lid body along an edge of the one side of the lid body, and
a second wall separated from the first wall and erected on the inner surface side of the lid body along the first wall.

3. The electrical connection box according to claim 1, wherein a through-hole for discharging a liquid flowing through the flow path to an outside of the box body is formed in the box body.

4. The electrical connection box according to claim 1, wherein the flow path is provided on one side adjacent to one surface of the box body provide with the connection terminal in the lid body in a mounted state.

5. The electrical connection box according to claim 1,
wherein the electrical connection box is mounted on a vehicle, and
the flow path is provided along a vertical direction in a state in which the electrical connection box is mounted on the vehicle.

6. An electrical connection box, comprising:
a box body;
a connection terminal; and
a wall,
wherein the box body has a polyhedron type for accommodating an electrical part,
the connection terminal is provided to protrude from an opening formed in at least one surface of the box body, and
the wall is erected along an edge portion of the opening at a predetermined interval from the edge portion in the box body.

7. The electrical connection box according to claim 2, wherein a through-hole for discharging a liquid flowing through the flow path to an outside of the box body is formed in the box body.

8. The electrical connection box according to claim 2, wherein the flow path is provided on one side adjacent to one surface of the box body provide with the connection terminal in the lid body in a mounted state.

9. The electrical connection box according to claim 3, wherein the flow path is provided on one side adjacent to one surface of the box body provide with the connection terminal in the lid body in a mounted state.

10. The electrical connection box according to claim 9, wherein the flow path is defined by:
a first wall erected on the inner surface side of the lid body along an edge of the one side of the lid body, and
a second wall separated from the first wall and erected on the inner surface side of the lid body along the first wall.

11. The electrical connection box according to claim 2,
wherein the electrical connection box is mounted on a vehicle, and
the flow path is provided along a vertical direction in a state in which the electrical connection box is mounted on the vehicle.

12. The electrical connection box according to claim 3,
wherein the electrical connection box is mounted on a vehicle, and
the flow path is provided along a vertical direction in a state in which the electrical connection box is mounted on the vehicle.

13. The electrical connection box according to claim 14, wherein the flow path is defined by:
a first wall erected on the inner surface side of the lid body along an edge of the one side of the lid body, and
a second wall separated from the first wall and erected on the inner surface side of the lid body along the first wall.

14. The electrical connection box according to claim 2,
wherein the electrical connection box is mounted on a vehicle, and
the flow path is provided along a vertical direction in a state in which the electrical connection box is mounted on the vehicle.

15. The electrical connection box according to claim 3,
wherein the electrical connection box is mounted on a vehicle, and
the flow path is provided along a vertical direction in a state in which the electrical connection box is mounted on the vehicle.

16. The electrical connection box according to claim 4,
wherein the electrical connection box is mounted on a vehicle, and
the flow path is provided along a vertical direction in a state in which the electrical connection box is mounted on the vehicle.

17. The electrical connection box according to claim 15, wherein the flow path is defined by:
a first wall erected on the inner surface side of the lid body along an edge of the one side of the lid body, and
a second wall separated from the first wall and erected on the inner surface side of the lid body along the first wall.

18. The electrical connection box according to claim 16, wherein the flow path is defined by:
a first wall erected on the inner surface side of the lid body along an edge of the one side of the lid body, and
a second wall separated from the first wall and erected on the inner surface side of the lid body along the first wall.

19. The electrical connection box according to claim 18 wherein a through-hole for discharging a liquid flowing through the flow path to an outside of the box body is formed in the box body.
